(19) United States
(12) Patent Application Publication
(10) Pub. No.: US 2005/0021251 A1
(43) Pub. Date: Jan. 27, 2005

(54) Analysis of the subsidence behavior of a test object

(75) Inventors: Klaus-Dieter Mueller, Nuernberg (DE); Thomas Voelkel, Bad Steben (DE)

Correspondence Address: SUGHRUE MION, PLLC, 2100 PENNSYLVANIA AVENUE, N.W., SUITE 800, WASHINGTON, DC, 20037, US

(73) Assignee: SIEMENS AKTIENGESELLSCHAFT

(21) Appl. No.: 10/807,324

(22) Filed: Mar. 24, 2004

Related U.S. Application Data
(63) Continuation of application No. PCT/DE02/03387, filed on Sep. 11, 2002.

(30) Foreign Application Priority Data
Sep. 24, 2001 (DE) 101 46 895.4

(51) Int. Cl. G01R 15/00

(52) U.S. Cl. 702/57

(57) ABSTRACT

A system for the automatic signal recording and for evaluation of the decay behavior of a test object following a mechanical impulse excitation. The system includes a coupling element (3) coupled to sensors (2, 13), which detect oscillations of the test object (24) and which convert the detected oscillations to analog oscillatory impulses. The system is further provided with an amplifier (5) adapting the amplitude of the analog oscillatory impulses, a low-pass filter (6) provided for avoiding aliasing effects, an analog to digital converter (7) converting the analog oscillatory impulses to digital data and an arithmetic unit (8) for oscillation analysis and evaluation of the data. The coupling element (3), the amplifier (5), the low-pass filter (6), the analog to digital converter (7) and the arithmetic unit (8) are combined in a compact mobile unit (1) and are connected in series to one another.

This is a Continuation of International Application PCT/DE02/03387, with an international filing date of Sep. 11, 2002, which was published under PCT Article 21(2) in German, and the disclosure of which is incorporated into this application by reference.

### FIELD OF AND BACKGROUND OF THE INVENTION

This invention relates to a system of signal recording and analyzing the subsidence behavior of a test object after mechanical pulse excitation.

It is possible to infer information and draw conclusions regarding the quality, functional reliability or condition of a manufacturing process for a product, in certain applications, from the mechanical subsidence behavior of a test object which has been excited by a mechanical pulse. This mechanical subsidence behavior is also referred to below as sound.

Current analysis systems are based on complex hardware and software. These systems require a high design complexity, which is in conflict with industry requirements for simple, inexpensive and easy-to-operate design for start-up operation and for automatic problem-free continuous operation.

### OBJECTS OF THE INVENTION

Objects of this invention include permitting automatic evaluation of the subsidence behavior of a test object after pulse excitation using a simple system.

### SUMMARY OF THE INVENTION

These and other objects are achieved, according to one formulation of the invention, by a system for automatic signal recording and analysis of the subsidence behavior of a test object after mechanical pulse excitation, including:
a coupling to sensors that are provided for detecting vibration of the test object and for converting the detected vibration into analog vibration signals,
an amplifier unit for amplitude adjustment of the analog vibration signals,
a low-pass filter unit to prevent aliasing effects,
an analog/digital converter for converting the analog vibration signals into digital data and
a computer unit for vibration analysis and for evaluation of the digital data,

whereby the coupler, the amplifier unit, the low-pass filter unit, the analog/digital converter and the computer unit are combined in a compact mobile unit in a series connection.

The components of the compact mobile unit perform the signal recording and analysis of the recorded signals. Algorithms optimized specifically for sound analysis can run on the computer unit. The amplifier unit ensures an optimum adaptation of the analog signal level to the subsequent analog/digital conversion. For a proper analysis, it is highly useful to perform low-pass filtering of the analog signal before the analog/digital conversion in order to prevent aliasing effects. The data converted by the analog digital converters is analyzed and evaluated directly by the computer unit. The system according to the invention preferably makes use of a combination of hardware, software and analytical knowledge of sound analysis, and provides a compact and easy-to-operate system.

In an advantageous embodiment of this invention, the sensors are integrated into the compact mobile unit. Therefore the compact mobile unit can be mounted directly on the test object to be evaluated without any additional external hardware. The proposed system is even less dependent on additional external systems if digital inputs and outputs are provided for connecting the computer unit to the mechanism for mechanical pulse excitation of the test object. By means of this connection it is possible for the computer unit to control the mechanism and thus control the complete test process from excitation to analysis of the data. By integration of power supply units for supplying power to the sensors, it is possible to connect external sensors to the compact mobile unit without requiring any other external power supply unit.

In another advantageous embodiment of this invention, a communications interface for connecting the computer unit to an external operator control and monitoring system is provided. This higher-level communications interface, which is based on an industry standard bus, for example, permits communication of the computer unit with the external operator control and monitoring system, especially for design and monitoring purposes. Thus, the software running on the computer unit can be accessed via an external parameterization and monitoring system and then modified and/or optimized.

In particular for the case when the mechanism for mechanical pulse excitation of the test object is triggered by an external automation system, it is proposed that the digital inputs and outputs be provided for connecting the computer unit to the external automation equipment. To have the possibility of making simple adjustments and visualization directly on the compact mobile unit, operator control and monitoring elements can be integrated into the compact mobile unit. In another embodiment of this invention, the computer unit is designed as a self-learning system. The software installed on the computer unit includes so-called learning procedures which include for example methods of automatic generation of significant features and for classification.

### BRIEF DESCRIPTION OF THE DRAWINGS

This invention is explained in greater detail below on the basis of the exemplary embodiments depicted in the figures.

FIG. 1 shows a schematic diagram of a system for automatic signal recording and analysis of the subsidence behavior of a test object,

FIG. 2 shows an embodiment of the system with an external sensor and control of pulse excitation by an automation device,

FIG. 3 shows an embodiment of the system with an internal sensor and control of pulse excitation by the internal computer unit, and

FIG. 4 shows a typical time signal of a vibration after pulse excitation.

### DETAILED DESCRIPTION OF THE PREFERRED EMBODIMENTS

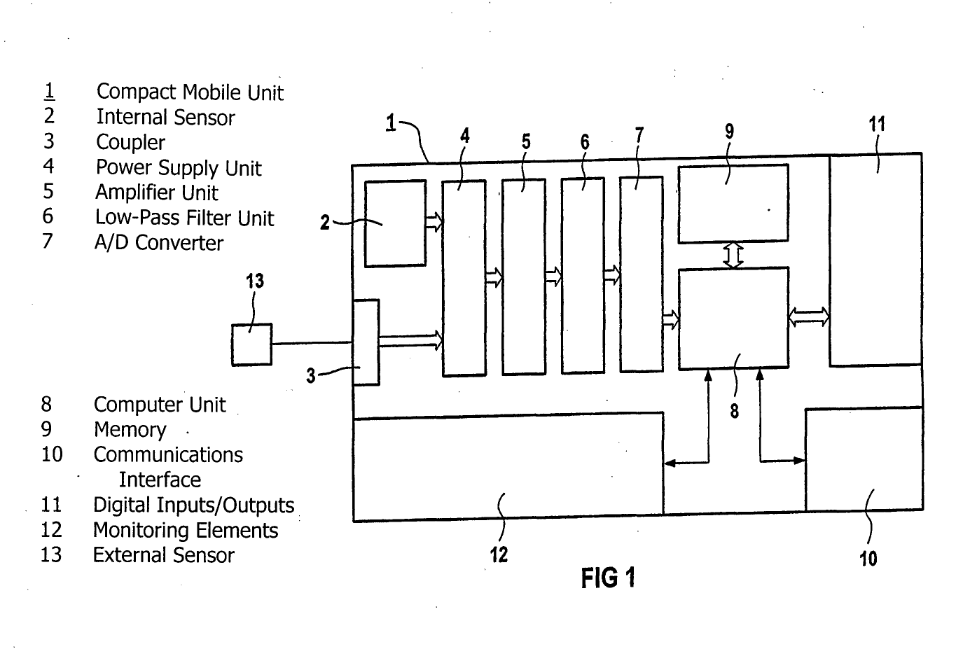

FIG. 1 shows a schematic diagram of an exemplary embodiment of a system for automatic signal recording and analysis of the subsidence behavior of a test object.

This shows a compact mobile unit 1 which is connected via a coupling element 3 to an external sensor 13. In addition the compact unit 1 contains an internal sensor 2, a power supply unit 4, an amplifier unit 5, a low-pass filter unit 6, an analog/digital converter 7, a computer unit 8, a memory 9, a communications interface 10, digital inputs and outputs 11, and operator control and monitoring elements 12.

Mechanical vibration of a test object is detected via the external sensor 13 or the internal sensor 2. The sensors 2, 13 are designed as laser vibrometers, for example, or as speed or acceleration pickups. Other known or applicable sensors could be used instead or in addition to the specific types of sensors just mentioned. The sensors 2, 13 are supplied with power by one or more power supply units 4. Such a power supply unit 4 is typically an electric current supply (20 mA) or an electric voltage supply, depending on the type of sensor 2, 13 used. The external sensor 13 is connected via a connection line and the coupling element 3 to the mobile unit 1, and the internal sensor 2 is integrated directly into the unit 1. The system may work with one or more internal sensors 2, and, depending on design, one or more external sensors 13.

A primary object of the sensors 2, 13 is to detect the mechanical vibrations of the test object and convert them into analog electric signals that are proportional to these vibrations. The analog signals are relayed via the power supply unit 4 to one or more amplifier units 5. The amplifier units 5 each amplify the amplitude of the analog signals in such a way that it is optimized for further processing, in particular for the analog/digital conversion. The amplified analog electric signals are relayed by the amplifier unit 5 to the low-pass filter unit 6. The low-pass filter unit 6 serves as a so-called anti-aliasing filter, i.e., an anti-aliasing low-pass filter. An anti-aliasing low-pass filter limits the spectrum of a signal that is continuous as to time and value to a certain bandwidth fg. This ensures that the original signal can be reconstructed exactly using samples derived in the downstream analog/digital conversions 7 at intervals of ≦(½)*fg. If the original signal cannot be reconstructed exactly because its bandwidth is too large from the standpoint of analog/digital conversion, then so-called aliasing effects occur readily, e.g., in the form of artifacts and corruption of the frequency spectrum. The filtered analog signals are converted to digital signals by the analog/digital converter 7.

This digital data is then processed further by a computer unit 8. The computer unit 8 is designed in this exemplary embodiment as a microprocessor. Software is loaded onto the microprocessor. This software is characterized in that it includes executable programs which execute methods designed specifically for analysis of non-steady-state signals (sounds). These include, for example, methods of flank detection, methods of determining the optimum recording period, for determining the resonance frequency, for determining the attenuation constants, for correlation calculation of multiple vibration events, for use of normalization functions for elimination of excitation differences, for filtering outstanding frequencies, for ratio determination of subsidence constants of different frequency components and/or for determining transmission function parameters from the correlation between excitation signal and vibration signal.

The computer unit 8 preferably is connected to a memory 9. This renders it possible to store results of prior measurements and/or computations in the memory 9. These results can then be used for further analyses—in particular for a trend analysis. Analysis of the digital data by the computer unit 8 includes a vibration analysis and an evaluation of the digital data on the basis of the results of the vibration analysis. Such an analysis can be performed with different goals and depends on the particular embodiment of the test object. The system proposed here can be used, for example, for testing materials (detecting cracks in roof tiles, fireclay brick, glass, castings, etc.), for leakage testing of containers (e.g., containers for foodstuffs) or for layer thickness determination (e.g., the layer deposited in a sublimator).

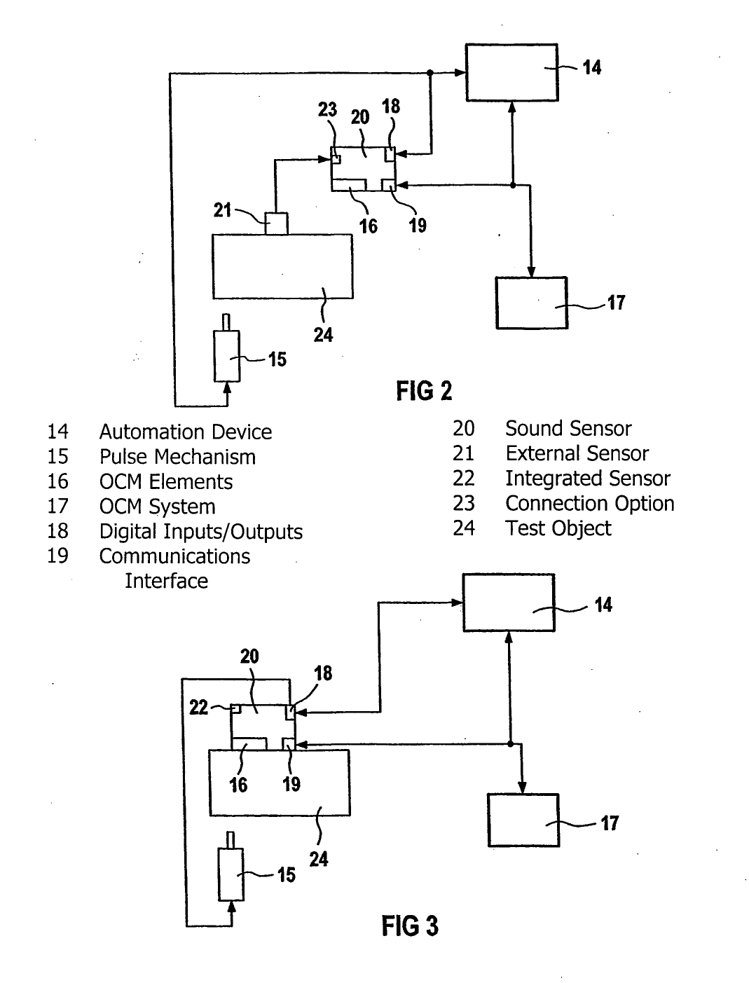

FIG. 2 shows an embodiment of the system with an external sensor 21 and control of the pulse excitation by an automation device 14. The compact mobile unit 1 is designed as a sound sensor 20 in this embodiment. The sound sensor 20 has a connection option 23 for an external sensor 21, operator control and monitoring elements 16, a higher-level communications interface 19 and digital inputs and outputs 18. Other components optionally contained in the sound sensor 20 are shown specifically here—e.g., components corresponding to the components of the mobile unit 1 in FIG. 1. The external sensor is mounted on a test object 24, which is excited by a mechanical pulse from a mechanism 15. The mechanism 15 is connected to an external automation device 14, which is connected via the digital inputs and outputs 18 to the sound sensor 20 and an external operator control and monitoring system 17. The external operator control and monitoring system 17 is connected to the sound sensor 20 via the communications interface 19.

In the design of the system corresponding to the diagram in FIG. 2, a test object 24 is excited to mechanical vibration by the mechanism 15. Such a mechanism 15 may be, for example, a pushrod driven by electric, electromagnetic or pneumatic means. Other known or applicable mechanisms could be used instead or in addition to the specific types of mechanisms just mentioned. The mechanism 15 receives control signals from the automation device 14. The sound sensor 20 combines the functions of signal processing and analysis of the subsidence behavior of the test object 24. The sound sensor 20 forms a compact, spatially limited component, e.g., by installing all the components in a common housing, which can thus be used as a mobile unit. The connections to the sensor 21, to the automation device 14 and to the operator control and monitoring system 17 are designed so they can easily be disconnected. The sound sensor 20 can be operated and monitored via the external operator control and monitoring system 17 and/or via operator control and monitoring elements 12 integrated into the module of the sound sensor 20. As such, the operator control and monitoring system 17 is provided also for complex operating functions, e.g., for intervention in the software of the sound sensor 20, while the integrated operator control and monitoring elements 12 tend to be used more for simple operating actions such as setting parameters. The external automation device 14 can also be operated and monitored via the external operator control and monitoring system 17.

FIG. 3 shows an embodiment of the system with an internal sensor 16 and control of pulse excitation by the internal computer unit. Similar components in FIG. 3 and/or in FIG. 2 are labeled with the same reference numbers. In contrast with the embodiment of the system according to FIG. 2, the sound sensor 20 here contains an internal sensor 22 and, furthermore the sound sensor 20 here and/or the computer unit 8 contained therein control(s) the pulse excitation of the test object 24 by means of the mechanism 15.

In the embodiment according to FIG. 3, the mechanism 15 for mechanical pulse excitation of the test object 24 is connected directly to the digital inputs and outputs 18 of the sound sensor 20. In addition, the sound sensor 20 may be mounted directly on the test object 24 by integration of the sensor 22 into the module of the sound sensor 20. Due to the compact, handy embodiment of the sound sensor 20, it can thus be mounted temporarily and at will on different test objects 24 entirely as needed. Since all the functions and components necessary for sound analysis are present and integrated into the module of the sound sensor 20 in the embodiment according to FIG. 3, the sound sensor 20 may be used for autarkic testing of test objects 24 without requiring other equipment. The results of the analysis can be read out and processed further by connected systems such as automation equipment 14 and/or operator control and monitoring systems 17 immediately or, if desired, at some later point in time by using the memory 9 of the sound sensor 24.

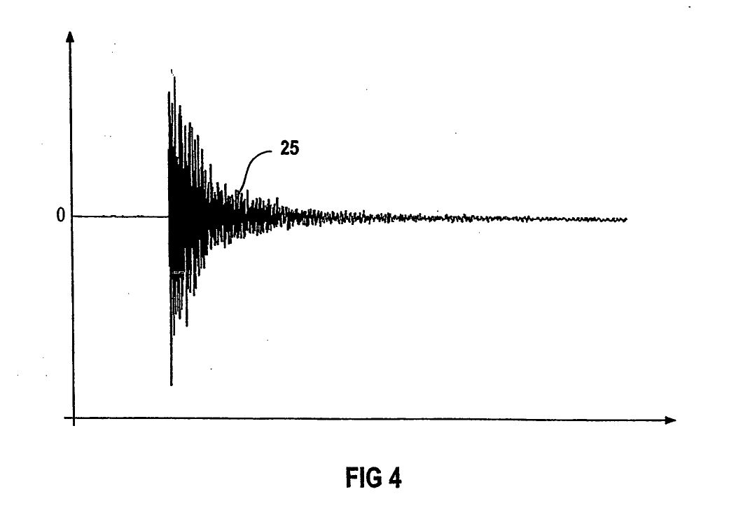

FIG. 4 shows a typical time signal 25 of a mechanical vibration of a test object 24 after mechanical pulse excitation. The amplitude values of the time signal 25 are plotted on the vertical axis of the diagram shown here and the time is plotted on the horizontal axis. The amplitude values in this example are the scaled measured values of the acceleration. The test object 24 is designed as a desublimator container. The point in time of pulse excitation, characterized by the sharp rise in amplitude of the time signal 25 immediately thereafter can be seen clearly. Since the desublimator container here was excited only with a single mechanical pulse, the envelope of the time signal 25 of the vibration decreases continuously after reaching a maximum. In this example, the vibration has subsided almost completely after half a second. This mechanical subsidence behavior is also referred to as sound.

To summarize, the present invention thus relates to a system having a simple design for automatic signal recording and analysis of the subsidence behavior of a test object after mechanical pulse excitation. The system contains a coupler 3 that couples to sensors 2, 13, which are provided for detecting vibration of the test object 24 and for converting the vibration thus detected into analog vibration signals, an amplifier unit 5 for amplitude adjustment of the analog vibration signals, a low-pass filter unit 6 for preventing aliasing effects, analog/digital converters 7 for converting the analog vibration signals into digital data and a computer unit 8 for vibration analysis and for evaluation of the digital data. The coupler 3, the amplifier unit 5, the low-pass filter unit 6, the analog/digital converter 7 and the computer unit 8 are combined in a compact mobile unit 1 in a series connection.

The above description of the preferred embodiments has been given by way of example. From the disclosure given, those skilled in the art will not only understand the present invention and its attendant advantages, but will also find apparent various changes and modifications to the structures and methods disclosed. It is sought, therefore, to cover all such changes and modifications as fall within the spirit and scope of the invention, as defined by the appended claims, and equivalents thereof.

1. A system for automatic signal recording and analysis of the subsidence behavior of a test object after a mechanical pulse excitation, comprising:
a coupler to sensors that are provided for detecting vibration of the test object and converting the detected vibration into analog vibration signals;
an amplifier configured to adjust the amplitude of the analog vibration signals;
a low-pass filter configured to at least reduce aliasing effects in the analog vibration signals;
an analog-to-digital converter configured to convert the analog vibration signals into digital signals; and
a computer configured to analyze the vibration and to evaluate the digital signals;
wherein the coupler, the amplifier, the low-pass filter, the analog-to-digital converter and the computer are combined in a compact mobile unit in a series connection, and the sensors are integrated into the compact mobile unit.

2. The system according to claim 1, further comprising at least one of a digital input and a digital output as a connection from the computer to a mechanism for mechanical pulse excitation of the test object.

3. The system according to claim 2, wherein the computer is configured to control the mechanical pulse excitation of the test object via the mechanism.

4. The system according to claim 1, further comprising at least one power supply configured to supply power to the sensors.

5. The system according to claim 1, further comprising a communications interface connecting the computer to an external operator control and monitoring system.

6. The system according to claim 1, further comprising at least one of a digital input and a digital output as a connection from the computer to an external automation device.

7. The system according to claim 1, wherein at least one operator control and monitoring element is integrated into the compact mobile unit.

8. The system according to claim 1, wherein the computer is an adaptive system.

9. An integrated mobile unit, comprising:
at least one sensor configured to detect mechanical vibrations of a test object into electrical signals;
a signal processor configured to produce digital evaluation signals in accordance with the electrical signals;
a computational component configured to analyze the evaluation signals with respect to a vibrational subsidence of the mechanical vibrations of the test object;
wherein the sensor, the signal processor and the computational component are integrated into the mobile unit and together form a series connection.
